(19) United States
(12) Patent Application Publication
(10) Pub. No.: US 2024/0176313 A1
(43) Pub. Date: May 30, 2024

(54) Method and Computer Device for Selecting a Measurement Sequence for a Coordinate Measuring Machine

(71) Applicant: Carl Zeiss Industrielle Messtechnik GmbH, Oberkochen (DE)

(72) Inventor: Jonas Frank, Stimpfach (DE)

(21) Appl. No.: 18/435,977

(22) Filed: Feb. 7, 2024

Related U.S. Application Data
(63) Continuation of application No. 16/843,695, filed on Apr. 8, 2020.

(30) Foreign Application Priority Data
Apr. 8, 2019 (EP) 19167949

(51) Int. Cl. G05B 13/04; G01B 5/012; G01B 11/00; G06F 17/18; G06F 30/20

(52) U.S. Cl. CPC G05B 13/041; G01B 5/012; G01B 11/005; G06F 17/18; G06F 30/20

(57) ABSTRACT

A method for selecting a measurement sequence for a coordinate measuring machine includes obtaining multiple surface regions of an object to be measured by at least one measurement sensor in respect of at least one predetermined property. The measurement sensor is arranged by the coordinate measuring machine at at least one specific position and/or with at least one specific orientation for the purposes of measuring a respective surface region. The method includes changing a measurement sequence, in which the surface regions should be measured, multiple times using at least one algorithm. The algorithm respectively ascertains a changed measurement sequence and an assessment variable for the changed measurement sequence within the scope of each change. The method includes selecting one of the measurement sequences based on the ascertained assessment variables. A relative relationship of at least two surface regions is specified as a condition to be observed by each measurement sequence

### CROSS-REFERENCE TO RELATED APPLICATIONS

This application is a continuation of U.S. application Ser. No. 16/843,695 filed Apr. 8, 2020, which claims priority to European Application No. 19 167 949.7 filed Apr. 8, 2019. The entire disclosures of the above applications are incorporated by reference.

### FIELD

The present disclosure relates to coordinate measuring machines and more particularly to methods and a computer device for setting a measurement sequence for a coordinate measuring machine.

### BACKGROUND

When measuring an object using a coordinate measuring machine, the coordinate measuring machine, as a rule, works through a sequence of measurement procedures. The measurement procedures are used to determine predetermined properties, in particular predetermined geometric properties, of surface regions of the object. Within the scope of a measurement procedure, the coordinate measuring machine ascertains the spatial coordinates of points on the object surface or in the surface region, from which it is subsequently possible to deduce the predetermined property. Examples of such properties, which are also referred to as a test feature, are a roundness, a parallelism, a flatness or a surface roughness.

By contrast, the surface regions can be assigned to certain geometric features of the object or, expressed differently, be formed thereby or comprise these. In general, the surface regions can be referred to as measurement elements. Examples of such surface regions are a cylinder (e.g., in the form of a bore, a groove or a projection), a circle, a sphere and a point.

One option for setting a measurement sequence, according to which a given object should be measured, consists of selecting the relevant geometric features or surface regions or, expressed in general terms, measurement elements, which should be measured. In particular, the properties (i.e., the test features) thereof that should be measured and thereby determined can be specified for each measurement element. The properties can also be determined relative and/or in relation to a further measurement element, e.g., as a distance or an angle of one measurement element with respect to a further measurement element. These can be set based on a CAD model of the object.

By way of example, an operator can select a bore of the object as surface region or measurement element and can specify that the diameter and the depth thereof should be determined as properties. Likewise, the operator can select a projection as a surface region and can specify that the height thereof should be determined as a property. This allows ascertainment of a plurality of corresponding surface regions and, in the case of complicated components, also a great number of surface regions together with properties respectively to be determined therefor. Expressed differently, the measurement task for an object, to be carried out by a coordinate measuring machine, may be composed of a plurality of measurement elements, together with test features respectively to be measured therefor.

For the purposes of measuring the surface regions, a measurement sensor is attached to the coordinate measuring machine in a manner known per se. The measurement sensor can operate on a tactile basis (i.e., with a tactile probe) or in contactless fashion (for example if it is embodied as an optical sensor, e.g., as a camera, and/or as an optical distance sensor). For the purposes of measuring the surface regions, this measurement sensor should be arranged by the coordinate measuring machine in at least one predetermined position and/or with a predetermined orientation. The position and/or orientation may emerge from the requirement of adopting an appropriate relative arrangement with respect to the object in order to be able to determine a desired property. By way of example, this then allows a certain point on the surface of the object to be probed or a region with a plurality of points to be imaged.

The surface regions can be spaced apart from one another, i.e., be separated from one another and/or be positioned on the object with at least not complete overlap. However, they may also at least partly overlap. The measurement sensor is moved relative to the object in order to reach the respective surface regions and/or at least to adopt the position(s) and/or orientation(s) assigned to each surface region. In particular, it can be moved from surface region to surface region if a plurality of successive surface regions should be measured. Expressed differently, the measurement sensor can be moved from position to position or orientation to orientation, with the positions or orientations being assigned to the successive surface regions.

Each of these non-measuring displacement movements requires time during which no object measurement occurs and therefore cannot be considered to be value-adding. Consequently, such movements, or the time required therefor, should be as short as possible.

Therefore, approaches are known, by means of which surface regions to be measured on an object are sorted within the meaning of a measurement sequence (or, expressed differently, a sequence to be worked through) in such a way that the required extent of movement between the surface regions is as small as possible.

In this context, U.S. Pat. No. 5,465,221 A teaches the creation of a so-called inspection plan, in which inspection points are sorted in an efficient sequence. To this end, reference is also made to the option of using “traveling salesman” algorithms.

In a manner known per se, “traveling salesman” algorithms are used to solve the so-called “traveling salesman problem” (TSP). Figuratively, these algorithms should ascertain an optimal route, e.g., the shortest and/or fastest route, for traveling through a plurality of regions or points, as a traveling salesperson would when driving through a plurality of localities. Here, such algorithms are also referred to as TSP algorithms.

There are a number of different types of algorithms that are directed to the solution of this problem or, in general, to the solution of a sorting problem. In general, these are optimization algorithms which set the sequence in such a way that a desired assessment variable (e.g., a so-called cost variable) is optimized (e.g., maximized or minimized, preferably minimized in the case of the cost variable).

To this end, the algorithm creates different sorts (or, expressed differently, routes or (measurement) sequences) and a value of an assessment variable is ascertained for each of the sorts. Considered over a plurality of sorts or routes, the assessment variable is subject to changes and has both local and absolute extremals or optimums. This becomes evident if the values thereof are plotted along a first coordinate axis and the associated sorts or routes are plotted along a second coordinate axis. The assessment variable being able to have local optimums or else an absolute optimum becomes evident from the formation of such a graph (or else independently thereof, for example by reading a value table). An example of such a graph is found in FIG. 5 of this disclosure, explained below. The associated optimal sorts can then be selected in order to carry out an actual workpiece measurement according to their prescriptions (i.e., to drive the coordinate measuring machine on the basis thereof).

However, TSP algorithms used previously are distinguished by a number of disadvantages. By way of example, they may require a very long computational time to find an absolute optimum. Additionally, should they have found a local optimum, they are not always able to find a further, possibly absolute optimum and/or able to determine whether this optimum is in fact only a local optimum or else the absolute optimum. Figuratively, known TSP algorithms cannot always escape from local optimums in order to ascertain further sorts with associated assessment variables. This also becomes evident from FIG. 5 for this disclosure, explained below.

Therefore, there can be delays, unwanted from the view of an operator, in the planning phase of object measurements using a coordinate measuring machine, for example delays in creating so-called testing plans. There can also be uncertainty as to whether an ascertained measurement sequence is in fact sensible or optimal or ensures a greatest possible efficiency.

Furthermore, previous TSP algorithms do not always allow conditions (e.g., boundary conditions) which should be observed during the measurement procedure to be taken sufficiently into account. Thus, even if a measurement sequence with preferred values of the assessment variable was ascertained, it may be found to be unsuitable for the practical object measurement. In turn, this may lead to delays on account of required replanning, or even to damage of the object or coordinate measuring machine when implementing this measurement sequence.

### SUMMARY

Consequently, the invention sets itself the object of improving the ascertainment of measurement sequences, suitable for practical use, for measuring an object using a coordinate measuring machine.

This object is achieved by the methods and a computer device as claimed in the accompanying independent claims. Advantageous developments are specified in the dependent claims.

It is understood that all of the aforementioned remarks, features, steps and interactions may also be provided in the present solution, provided nothing else is specified or this is evidently not the case.

In general, the invention provides for the use of a plurality of algorithms to avoid the aforementioned problems, each algorithm independently varying or changing respectively one measurement sequence. In particular, there can be a change, preferably multiple changes, in the measurement sequence using each of the algorithms and assessment variables can be ascertained by means of the algorithms for each changed measurement sequence.

This offers various advantages over the previous use of only one TSP algorithm. Firstly, the number of different measurement sequences for which assessment variables are ascertained can be increased, and so a measurement sequence can be selected as suitable from a greater number thereof. Also, this can be implemented more quickly, i.e., a corresponding greater number of measurement sequences can be considered within a specified time interval than if use is made of only one algorithm. Further, this increases the probability of at least one of the algorithms being able to escape a local optimum (in particular a local minimum) of the assessment variable after arriving at the latter and/or of none of the algorithms being caught in a local optimum.

Likewise, the algorithms can be combined in such a way that they at least partly compensate a weakness of the respective other algorithm. By way of example, a fast algorithm and a slow algorithm can be combined, with the speed in general being able to refer to a computational speed explained below. Then, the operator themselves can decide whether they accept an optimum of the assessment variable ascertained by means of the fast algorithm, which may however only be a local optimum, or whether they wait for the slower algorithm to find a further and possibly absolute optimum. It is also possible to combine algorithms of different quality or with different output frequencies of intermediate results. Further, according to one embodiment, the algorithms can start with different initial measurement sequences, which is accompanied by the advantages explained below.

In detail, a method for selecting a measurement sequence for a coordinate measuring machine is proposed, including:
a) obtaining a plurality of surface regions of an object that should (each) be measured by a measurement sensor in respect of at least one predetermined property, wherein the measurement sensor should be arranged by the coordinate measuring machine at at least one specific position (e.g., surface region-specific position) and/or with at least one specific orientation (e.g., surface region-specific orientation) for the purposes of measuring a respective surface region;
b) changing a measurement sequence, in which the surface regions should be measured, multiple times using a first algorithm and using a second algorithm, wherein the algorithms each ascertain a changed measurement sequence and an assessment variable (or a value for this assessment variable) for this (changed) measurement sequence within the scope of each change;
c) selecting one of the measurement sequences based on the (overall) ascertained (values of the) assessment variable(s).

Further, the method may optionally comprise the step of carrying out the selected measurement sequence using a coordinate measuring machine and/or the step of driving the coordinate measuring machine to carry out the selected measurement sequence.

The method is also directed to a computer device which is configured to carry out a method of the aforementioned type, but also carry out any other variant, development and embodiment described below. The computer device can comprise at least one microprocessor. In general, the computer device can be configured to process and/or execute program instructions and, in particular, the aforementioned algorithms, and to carry out the individual method steps on the basis thereof.

In particular, the computer device can comprise a storage device (e.g., a digital and/or electronic storage device) or can be connected to the latter and can receive the surface regions of the object from the latter. However, the computer device can also be configured to ascertain the corresponding surface regions and the properties to be measured, for example using a CAD model and/or based on user inputs. Further, the computer device can compare the assessment variables or select the best possible assessment variable in view of a predetermined selection criterion for the purposes of selecting the measurement sequence.

The surface regions can be regions with predetermined geometric properties and, in particular, can be measurement elements of the aforementioned type. A surface region can also be only punctiform or define a measurement point. Consequently, the measurement sequence can also define a succession of points, according to which a plurality of measurement points should be captured (e.g., measured in respect of their coordinates) by the measurement sensor. Mixed forms are also conceivable, where two-dimensional surface regions and one-dimensional surface regions (i.e., individual measurement points) form a measurement sequence within the meaning of the invention.

The predetermined properties can be the test features discussed herein. The measurement sensor can be a tactile sensor and comprise a stylus, for example. Alternatively, the measurement sensor can be an optical sensor and comprise, e.g., a camera, by means of which one or more camera image(s) of a surface region are captured for the purposes of measuring the surface region.

The coordinate measuring machine can be embodied as per any conventional design and, for example, comprise a multiplicity of machine axes (in particular linear axes) that are disposed orthogonal to one another. This is a portal-type coordinate measuring machine according to one variant. In general, the coordinate measuring machine can be configured to arrange and/or align the sensor relative to the object within a working space, in which the object to be measured is also arranged. To this end, it may also comprise an object rotary stage. Further, the coordinate measuring machine can be configured to ascertain coordinate values of the object, for example a currently probed point on the object surface, by reading out the own machine axis positions and/or based on the ascertained measurement sensor signals. An example of a coordinate measuring machine also usable in the present case is found in EP 0 790 478 B1 by the applicant and explained therein with reference to FIG. 1.

The coordinate measuring machine can move the measurement sensor relative to the object for the purposes of assuming the positions and/or orientations for each surface region. In particular, this applies when a change should be undertaken from a surface region that has already been measured to a subsequent surface region. Then, the coordinate measuring machine can move the sensor from a position for measuring the previous surface region to a position of the subsequent surface region, or else can accordingly change an orientation (from an orientation for measuring the preceding surface region to an orientation for measuring the subsequent surface region).

Such movements between the surface regions can be set based on the measurement sequence or defined in accordance therewith. However, these movements may represent movements without added value or generally unwanted movements, which should consequently be kept as short as possible. By means of the algorithms, these should preferably be optimized towards movements that are correspondingly quickly implementable where possible.

Multiple changes in the measurement sequence or, expressed differently, multiple variations thereof can occur in virtual fashion or, expressed differently, in computational fashion. By way of example, a plurality of different virtual measurement sequences can be defined within the scope of one embodiment of the algorithms, wherein a respective value of the assessment variable is calculated and/or determined by simulation for each of these virtual measurement sequences. Examples to this end are explained below based on the figures. Then, an algorithm can also make a decision about the type and/or the extent of a change in the measurement sequences based on the assessment variable.

However, it is also possible to read the assessment variable based on values stored in advance and to ascertain it thereby. By way of example, the assessment variable can be calculated in advance for individual measurement sequences and/or at least for individual movements between selected surface regions. Depending on the current measurement sequence, this information calculated in advance can be read and combined to form the assessment variable of the (overall) measurement sequence. Such a procedure also constitutes an ascertainment of the assessment variable within the meaning of the present invention.

In particular, the measurement sensor movements and/or machine axis movements can be ascertained for each measurement sequence, which movements are at least required to move the measurement sensor between the surface regions (i.e., to move the latter between the successive surface regions according to the measurement sequence).

However, additionally or alternatively, movements for driving to a plurality of positions and/or for adopting a plurality of orientations within a surface region may also be considered (i.e., the movements required to measure the properties assigned to this surface region). Expressed differently, the movements for determining the test features may additionally or alternatively at least co-determine the value of the assessment variable.

In general, the measurement sensor movements and/or machine axis movements can be ascertained by simulation or by means of NC algorithms for the purposes of ascertaining values of the assessment variable based on necessary movements. In the case of a calculation in advance, these movements can also be read, for example be composed to an overall movement procedure depending on surface regions following one another according to a current measurement sequence.

In particular, a measurement sensor position and/or measurement sensor orientation adopted last in a previously measured surface region (i.e., an end position or end orientation) and a measurement sensor position and/or measurement sensor orientation to be adopted first in a subsequent surface region (i.e., a start position or start orientation) can be considered. The movements considered for setting the assessment variable can then be the movements between the corresponding start and end positions and/or start and end orientations

If the measurement sensor is an optical sensor and, in particular, a camera, it is possible to take account of how many orientations and/or positions should be adopted in order to be able to ascertain the desired properties. It is possible to consider, once again, the (displacement) movements of the measurement sensor required therefor and, in particular, the extent and distance thereof. In principle, however, it could only be the number of individual movements that are taken into account. In this case, it is advantageous if information items (in particular images) are capturable with only one camera orientation and/or in only one camera position, by means of which information items a plurality of properties of the same or different surface regions can be ascertained simultaneously. In this case, the costs or movements related to a surface region to be measured can even be set to zero if this surface region is also already capturable, in parallel as it were, when measuring another surface region.

Probe interchange procedures can also be included in the value of the assessment variable in a manner known per se. In this case, there can be an underlying fixed value (e.g., as a time loss or time requirement for the probe interchange, which each need not be determined anew for each probe interchange procedure). However, it is also possible to take account of specific circumstances of the probe interchange procedure, for example the surface region from which a probe store should be approached and/or which surface region should be approached after the probe store.

Based on a set measurement sequence, it is possible to automatically identify, in a manner known per se, that a probe interchange is necessary, for example if surface regions to be measured in succession according to the measurement sequence, and the properties to be determined therefor, require different probes and/or if the relationship between the properties to be determined and the probes required to this end is stored in a database. Alternatively, this relationship can also be stored directly in a test plan.

The algorithms are preferably sorting algorithms which set the sequence in which the surface regions should be measured by means of an appropriate sort. An example of such sorting algorithms are TSP algorithms of the type set forth at the outset which can likewise be used in accordance with the invention. The first and second algorithm can be similar. However, this may also be different algorithms. Specific examples and advantages of combinations of different or similar algorithms are specified below.

The assessment variable can be a cost variable, as is usually used in the context of general optimization algorithms. The assessment variable and, in particular, the cost variable can consequently specify a variable and/or property that should be minimized by means of the algorithms and by setting a suitable measurement sequence. However, it can likewise be a variable to be maximized. An example of the assessment variable is a measurement time duration required overall for measuring the object. Likewise, the extent (e.g., the distance) of the required machine axis movements can be considered, particularly in view of the movements between the individual surface regions.

By contrast, movements for determining the properties within a surface region or in relation to only one surface region can remain unconsidered when ascertaining the assessment variable and/or can have no influence on the assessment variable in general. This is based on the idea that such movements could already be defined in advance and, where applicable, could already have been optimized. Depending on the property to be measured or depending on the test feature to be measured, the movements can then be carried out in a predetermined manner without this requiring a further optimization by the algorithms presented herein.

By way of example, a diameter can always be ascertained in the same way, and so the movements to this end need not be determined and assessed anew. However, should a plurality of test features be determined for one surface region, at least movements between positions and/or orientations for determining these test features can also be taken into account when ascertaining the assessment variable. In this case, every test feature or each measurement point or a group of measurement points for determining a test feature can also form a surface region within the meaning of the invention and a sequence of the test features can be changed and assessed within the meaning of a measurement sequence. Then, the coordinates of the measurement points from which the test feature is subsequently ascertained can then be ascertained as property to be determined.

In summary, the algorithms and the assessment variable thereof can consequently preferably relate to the movements between the surface regions only and/or the measurement sequence can define such movements, at least indirectly. Additionally, the fact that optional virtual spaces, within which arbitrary measurement sensor movements are not possible so as to avoid collisions, can be defined around the surface regions can also be taken into account in this case. Instead, only a movement perpendicular to the object surface, for example, may be admissible within these spaces. The movements used to ascertain the assessment variable may consequently also relate only to those movements that occur between the surface regions and outside of such virtual spaces.

To the extent that reference is made to an optimum here, this can include both a local optimum and an absolute optimum. An optimum can be both a minimum and a maximum. Furthermore, the term optimum can generally relate to an optimal value of the assessment variable. An optimal measurement sequence can consequently be a measurement sequence in which the assessment variable adopts an optimal value.

Selecting the measurement sequence based on the ascertained assessment variables may comprise selecting a measurement sequence with an assessment variable that satisfies a predetermined selection criterion. By way of example, the selection criterion can define that the best assessment variable, optimal (e.g., minimal or maximal) assessment variable or, in general, a preferable assessment variable with the associated measurement sequence is selected. By way of example, it is possible to select the measurement sequence with the shortest measurement time duration or with the smallest number of machine movements (e.g., measured as a movement distance).

A development of the invention provides for the measurement sensor (e.g., of the coordinate measuring machine) to be moved relative to the object for measuring successive surface regions so as to adopt the at least one position and/or orientation assigned to the surface regions in each case. As explained, these movements and, in particular, these movements only can be used to ascertain a value of the assessment variable. By contrast, movements for determining the properties of the surface region, for example which occur within the surface region and/or which are provided for changing positions and/or orientations within a single surface region, can remain unconsidered when ascertaining the assessment variable.

In summary, the assessment variable can therefore be ascertained based on the movements of the measurement sensor which are required to reach (and/or approach) successive surface regions (e.g., according to a currently considered or changed measurement sequence). In particular, reaching may comprise the at least one position and/or at least one orientation (and, in particular, a start position or start orientation as explained herein) of the surface region being reached or adopted by the measurement sensor.

An ascertainment based on the movements can comprise the assessment variable being determined proceeding from these movements and/or at least indirectly based on the movements. By way of example, the assessment variable can specify the power consumption or a path length (e.g., cumulative path length) of carried-out movements (e.g., measurement sensor movements), both of which are preferably determined based on the ascertained movements required.

As mentioned, the algorithms can each be based on (solution) approaches for solving the traveling salesman problem. This can be understood to mean that an optimal route between locations to be reached and, in the present case, between surface regions to be reached by the measurement sensor should be ascertained, which route optimizes the assessment variable in a desired way (e.g., maximizes or minimizes the latter).

Such algorithms are known, but differ from one another in terms of properties such as a computational speed, quality, an output frequency of intermediate results and, in general, in the capability of escaping from local optimums and, in particular, local minimums of the assessment variable. Examples of such algorithms include the so-called tabu search algorithms, nearest neighbor algorithms, k-opt algorithms (e.g., a 3-opt algorithm), Christofides heuristic algorithms and guided local search algorithms.

The computational speed can be understood to mean the speed required by the algorithm to reach an optimal result from its point of view (e.g., in order to find an at least local optimum).

The quality can be understood to mean the resolution and/or, in general, the accuracy of an algorithm optimum, for example the extent to which a found optimum deviates from an actual (i.e., objective) optimum and, in particular, an absolute optimum. On account of the changes carried out by the algorithms and, in particular, on account of an extent of the change, actually finding a corresponding objective optimum is not always ensured, and nor is an optimal result from the point of view of the algorithm in fact ensured to be optimal when objective aspects are considered. Further, the quality may relate to other properties of the algorithm or at least be co-determined thereby. By way of example, such properties could be the capability of proceeding from a specified initial route, the memory use or an output frequency of progress information.

If algorithms are compared to one another herein, for example in respect of the aforementioned properties, it is understood that these comparisons relate to properties and relationships obtainable on average, for example if the algorithms are used for a plurality of different optimization tasks. Expressed differently, this may relate to objectively applicable properties from the point of view of a person skilled in the art which, however, depending on the initial situation and specific optimization task, may not always be directly applicable but may arise accordingly when considered over a plurality of optimization tasks. By way of example, for an individual case and, for example, on account of a randomly selected particularly suitable initial route, an algorithm referred to herein as a slower algorithm may reach an optimal result faster than an algorithm referred to herein as quick, with the latter, however, starting from a comparatively unfavorable initial route. However, this does not apply if these algorithms are applied to a plurality of different initial routes and, for example, to at least ten different initial routes.

According to one embodiment of the methods and computer devices presented herein, the first algorithm ascertains an initial measurement sequence as a start sequence for the second algorithm. In this case, the first and the second algorithm preferably differ from one another. In particular, the first algorithm can be configured to ascertain a result that is optimal from its point of view faster than the second algorithm. By contrast, the second algorithm can be more accurate (i.e., ascertain an objectively applicable optimum with a higher probability) and/or can escape from local optimums and, in particular, minima with a higher probability in order to possibly find an even better optimum and, in particular, the absolute optimum.

The initial measurement sequence can be a so-called initial route. The latter (but also the general initial measurement sequence) can be used by the second algorithm to undertake successive changes by building thereon. By way of example, depending on the rules stored in the algorithm, changes from this initial route may occur, to be precise in a manner or direction in which a suspected optimum (e.g., an absolute optimum) is located.

In particular, a measurement sequence with an at least local optimum of the assessment variable can be able to be found more quickly with the first algorithm than with the second algorithm. By way of example, the reason for this may lie in the fact that the first algorithm undertakes greater changes (i.e., in general has a less fine resolution) and consequently reaches the vicinity of a possibly optimal result more quickly. In particular, the first algorithm can be a nearest neighbor algorithm or a k-opt algorithm (preferably with low k of, e.g., less than three or at least lower than that of the second algorithm). In general, the following applies to the k-opt algorithms: The higher k, the greater detours (which, e.g., lengthen the route) are accepted or, expressed differently, the greater the accepted extent of possible deteriorations in the assessment variable in the case of a new measurement sequence variation. This allows local minima to be escaped. On the other hand, this may increase the computation duration since more permutations overall have to be worked through. In general, the number of changes that are undertaken by an algorithm can thus also have an influence on the computation time.

In addition or as an alternative thereto, the probability of ascertaining a measurement sequence with a further, at least locally optimal assessment variable after a measurement sequence with an at least locally optimal assessment variable has already been found may be greater with the second algorithm than with the first algorithm, for example because the second algorithm can once again escape from an obtained local optimum with a higher probability or can once again leave the latter with a higher probability. By way of example, this may be achieved by virtue of the second algorithm having a heuristic and/or meta-heuristic, while the first algorithm preferably does not have this, or else a less accurate heuristic (e.g., a so-called 2-opt heuristic for the first algorithm and a 5-opt heuristic for the second algorithm). A heuristic can facilitate an approximate solution of optimization problems (e.g., the present assessment variable) in a manner known per se. The approximate approach represents an alternative to brute force or complete solution approaches that consider all permutations. To this end, the heuristic can define computation rules, computation steps or general procedures in relation to how such an optimization problem should be solved approximately. A meta-heuristic can be a heuristic that is used within an algorithm (e.g., selectively) for escaping local optimums.

All of the explained variants in which an algorithm ascertains an initial route for the other algorithm offer the advantage that an absolute optimum may be reached faster. By way of example, the first algorithm can already find the absolute optimum, which is then only still confirmed by the second algorithm, or the second algorithm must only carry out a few changes in order to reach this absolute optimum. In particular, this applies in comparison with the case where the second algorithm starts with any initial route without corresponding preparation. These advantages will still be explained in more detail below in conjunction with the description of the figures.

According to a further embodiment of the methods and computer devices according to the invention, the first and the second algorithm are carried out at least partially in parallel, i.e., they at least partly overlap with one another in time. In particular, the algorithms can be started simultaneously or with only a few seconds or minutes of a relative delay (e.g., less than 30 seconds or less than 3 minutes).

In this case, it is possible to use similar algorithms which, however, proceed from different initial measurement sequences (or else initial routes). Expressed differently, the first and the second algorithm can be similar but proceed from different initial measurement sequences.

By way of example, a general initial measurement sequence may be specified; however, it may have a different noise depending on the algorithm or, expressed differently, it may be varied differently by means of, e.g., a random variable or in deterministic fashion before it is processed by the algorithms (i.e., successively changed and optimized by the latter).

This increases the probability of at least one of the algorithms already starting in the vicinity of an optimum and thus reaching an optimal result with only a few changes. This can also increase the probability of at least one of the algorithms not already satisfying a termination criterion prematurely and/or reaching a state where it is no longer able to find a further optimum, for example as it can no longer escape from a local minimum.

However, the algorithms can also be different from one another if these are initially carried out partially in parallel. Providing different initial measurement sequences is not mandatory in that case; however, it may still occur according to the invention.

In particular, the algorithms may differ in respect of the computational speed and/or an output frequency of intermediate results. The intermediate results can be a measurement sequence currently assessed as optimal, which can be updated whenever an even better or more optimal measurement sequence was found, for example. It may also relate to a progress specification in general, for example relating to how far the algorithm is away from a suspected global optimum or how many changes or variations of the measurement sequence have already been worked through.

Additionally or alternatively, the algorithms may also differ from one another in respect of the quality, as explained above, or in respect of other properties and/or they may have different meta-heuristics. By way of example, differences may once again be in the form of one of the algorithms being faster and/or of one of the algorithms being able to escape from a local optimum with a higher probability (or being able to find a further optimum after having already found one optimum).

By way of example, it was found to be advantageous to combine a guided local search algorithm with tabu search algorithm or, more precisely, to carry these out at least partially in parallel. The former is distinguished by a higher computational speed whereas the latter outputs intermediate results more frequently. This is advantageous to the effect of the previously ascertained best intermediate result in the case of premature termination, for example effected by the operator, often being selected for further use. The probability of an intermediate result in the vicinity of the actual optimum already being available is higher in the case of a higher output frequency.

Further, provision can be made for a predetermined termination criterion to be defined for at least one of the algorithms. As soon as this is satisfied, the algorithm can suppress further changes in the measurement sequence and, for example, an assessment variable previously ascertained as optimal can be selected, together with the associated measurement sequence, as the best result.

In particular, a maximum admissible number of changes in the measurement sequence without finding an at least locally optimal assessment variable can be defined as a termination criterion for at least one of the algorithms. In particular, this termination criterion can only be satisfiable or can only come to bear after an (at least local) optimum has already been found. Then, if a further optimum is not found within a predetermined number of changes in the measurement sequence, it is possible to deduce that the algorithm is already located in the vicinity of the absolute optimum and/or cannot escape from the previously ascertained optimum.

Such a termination criterion ensures that the computation time is not unnecessarily increased or an operator is informed in sufficiently timely fashion that it does not appear as if any further improvements are attainable.

In this context, the maximum admissible number of variations can be selected based on the number of (obtained) surface regions. In particular, this admissible number can be chosen to be proportional to the number of surface regions and/or the following can apply in general: the greater the number of surface regions, the higher the admissible number.

This accounts for the fact that there also are an increased number of options for changes and/or for setting changed measurement sequences as the number of surface regions increases. Consequently, in the case of a correspondingly increased admissible number, the significance can be increased to the effect of the assumption in fact being able to be made that no further improvement is obtainable within an acceptable timeframe should the algorithm be terminated.

As a further aspect of the invention, the measurement sequences can be defined and/or changed in such a way in addition or as an alternative to step b) that the surface regions are measured by a plurality of coordinate measuring machines with preferably a measurement sensor in each case and/or the surface regions are divided between these coordinate measuring machines. Thus, the object can be measured by a plurality of coordinate measuring machines. These can each measure a subset of the surface regions obtained. The division as to which coordinate measuring machine measures which surface region may likewise be a constituent part of a measurement sequence described herein, or it may be set by the latter. Thus, provision could also be made for at least one algorithm (but optionally also for two algorithms), which changes the measurement sequence while changing this division and which also ascertains an assessment variable for each correspondingly changed measurement sequence. The ultimately selected measurement sequence can then yield the most optimal assessment variable (e.g., the fastest assessment variable). However, changing the measurement sequence may also mean that there is no new division although the sequence in which the coordinate measuring machines each measure the surface regions thereof changes. However, it is preferable according to the invention if this division is changed at least once and preferably multiple times within the scope of the method.

The algorithm used to this end can be an algorithm that is based on approaches for solving a so-called “multiple traveling salesman problem” or a “vehicle routing problem”, both of which are subtypes of the traveling salesman problem. Additional conditions to be satisfied can be defined for the application on a plurality of coordinate measuring machines, for example that both coordinate measuring machines (or both “vehicles” from the view of an algorithm) must not operate in the same region simultaneously (e.g., in order to prevent collisions).

Moreover, if there is only one specimen available of certain probes or measurement sensors, the route can be optimizable in such a way that the coordinate measuring machines only have to wait as little as possible or for as short a time as possible, for example if the same sensor has to be used at the same time by the coordinate measuring machines for their current measurement task.

Further, provision can be made for a so-called “vehicle routing problem with time window” to be defined and for solution algorithms to be used to this end. As a result of this, measurement elements that depend on one another can be measured with a short temporal distance or within a time window that is specified as a condition.

In summary, the invention therefore also relates to a method for selecting a measurement sequence for a plurality of coordinate measuring machines, including:
obtaining a plurality of surface regions of an object that should be measured by at least one of the coordinate measuring machines (e.g., initially any coordinate measuring machine or a coordinate measuring machine according to a division to be set) and by a measurement sensor of the coordinate measuring machine in respect of at least one predetermined property, wherein the measurement sensor should be arranged at at least one specific position and/or with at least one specific orientation for the purposes of measuring a respective surface region;
changing a measurement sequence, in which the surface regions should be measured and divided between the coordinate measuring machines, multiple times using at least one algorithm (but optionally also using a second algorithm according to any one of the variants above), wherein the algorithm respectively ascertains a changed measurement sequence and an assessment variable (or a value for this assessment variable) for the changed measurement sequence within the scope of each change; and
selecting one of the measurement sequences based on the overall ascertained (values of the) assessment variable(s).

Likewise, the invention relates to the use of an algorithm, in particular an algorithm based on approaches to solving the (in particular multiple) traveling salesman problem, for setting a division of surface regions of an object to be measured such that one portion thereof is measured by a first coordinate measuring machine and another portion (in particular the remaining portion) is measured by at least one further coordinate measuring machine. Accordingly, a method according to the invention provides for a portion of surface regions of an object to be measured to be divided in such a way that one portion thereof is measured by a first coordinate measuring machine and another portion (in particular the remaining portion) is measured by at least one further coordinate measuring machine, for the purposes of which an algorithm of the aforementioned type is preferably used. The coordinate measuring machines can measure the object at least partially simultaneously. In all such variants, conditions specified above and conditions specified below can be taken into account for defining a suitable division and/or measurement sequence.

Further, the invention also relates to a method for selecting a measurement sequence for a coordinate measuring machine, including:
obtaining a plurality of surface regions of an object that should be measured by a measurement sensor in respect of at least one predetermined property, wherein the measurement sensor should be arranged by the coordinate measuring machine at at least one specific position and/or with at least one specific orientation for the purposes of measuring a respective surface region;
changing a measurement sequence, in which the surface regions should be measured, multiple times using at least one algorithm (but optionally also using a second algorithm according to any one of the variants above), wherein the algorithm respectively ascertains a changed measurement sequence and an assessment variable (or a value for this assessment variable) for the changed measurement sequence within the scope of each change; and
selecting one of the measurement sequences based on the overall ascertained (values of the) assessment variable(s). A condition to be observed by each measurement sequence specifies a relative relationship (e.g., a temporal or hierarchical relative relationship) between at least two surface regions.

All of the explanations, developments, alternatives and embodiments, provided above and below, in respect of equivalent features of the method specified first, in which no corresponding condition is mandatory, also apply to the present method, in which a corresponding condition is taken into account. Additionally, a method that takes account of a condition can be combined with any variant of the method specified first, and so there can also be a method in which two different algorithms are provided and, additionally, one of the conditions explained herein applies

The condition can be taken into account by the algorithms when changing the measurement sequence. Measurement sequences that infringe on the condition can therefore be assessed as invalid and can be assessed no further and/or cannot be selectable in step c). However, it is also possible to carry out such a check with a separate unit (e.g., a software unit), which only subsequently sorts or declares invalid measurement sequences that were changed and assessed by the algorithms.

Thus, the method may comprise the step of the algorithms changing the measurement sequence while taking account of a corresponding condition (i.e., only generating and/or assessing measurement sequences that have been changed in valid fashion). However, the step of subsequently checking and possibly rejecting measurement sequences, changed and assessed by the algorithms, in respect of the condition to be observed may also be provided.

According to one variant, the relative relationship to be observed according to the condition defines a relative sequence (or the hierarchy) of the at least two surface regions within the measurement sequence. In particular, one of the surface regions may be specified as having to be measured before another one of the surface regions since the measurement results of the one surface region co-determine the measurement of the other surface region and/or because there is a dependency therebetween. By way of example, this applies if a first of the surface regions comprises a first geometric feature and the extent to which a geometric feature of the second surface region has a predetermined relative relationship with the geometric feature of the first surface region and/or is parallel thereto, for example, should be determined for the second surface region. By way of example, determining the parallelism between two cylinders can be specified as a measurement task. In this case, the first cylinder is scanned and only a circular trajectory is preferably measured on the second cylinder, level with where the other cylinder had the greatest positive deviation from a target diameter, for example. This can firstly save time and secondly allows critical points to be captured in improved fashion.

In addition or as an alternative thereto, the observance of a maximum admissible time interval can be specified as a relative relationship to be observed according to the condition, within which time interval the surface regions should or must be measured when the measurement sequence is carried out. This is based on the idea that conditions that are as similar as possible should prevail when measuring the surface regions. In particular, this can ensure that comparable temperature conditions are present. By way of example, the fact that the measurements of two surface regions must not lie apart by more than 1 minute or by more than 5 minutes may be specified as a time interval.

As an alternative to a condition relating to the relative relationship, an observance of freedom from collisions may also be specified as a condition. This may take into account that no collisions with the object or other disturbance contours in the working space of the coordinate measuring machine should occur when moving the measurement sensor according to the measurement sequence (i.e., between the surface regions following one another according to the measurement sequence). This can be ascertained by calculating (e.g., by NC algorithm) and/or simulating the movement path of the measurement sensor between the surface regions that follow one another according to the measurement sequence, for example with a comparison with a model of the object and/or of the working space in the coordinate measuring machine.

Methods in which conditions of the aforementioned type are taken into account can also be carried out by a computer device according to any type described herein, with such a computer device being a further general constituent part of the present invention. Expressed differently, the invention also relates to a computer device for carrying out methods that take account of conditions of the aforementioned type.

A processing device of the computer device can be configured to take account of the corresponding condition when carrying out algorithms and/or to assess, during the selection or prior to the selection, the measurement sequence to the effect of whether or not they meet the condition. The condition can be saved in a memory device of the computer device. Further, the computer device can check whether the condition is observed by way of simulations and/or calculations. To this end, it can calculate or simulate the movements of the measurement sensor required according to the measurement sequence, the measurement sensor requiring these movements to reach from surface region to surface region according to the stipulation of the measurement sequence (i.e., to be able to measure the surface regions that follow one another according to the measurement sequence).

In general, the computer device can be comprised by a coordinate measuring machine or it can be connected to the latter and the computer device can optionally drive the coordinate measuring machine according to the stipulation of the selected measurement sequence and/or for carrying out the latter.

### BRIEF DESCRIPTION OF THE DRAWINGS

Example embodiments of the invention are explained below with reference to the accompanying schematic figures. Features that coincide in their nature and/or function may in this case be provided with the same reference signs throughout the figures.

FIG. 1 shows a schematic illustration of an object and its surface regions that should be measured by a coordinate measuring machine within the scope of a measurement sequence.

FIG. 2A shows an illustration of an example measurement sequence for measuring surface regions of FIG. 1.

FIG. 2B shows an illustration of an example measurement sequence for measuring surface regions of FIG. 1.

FIG. 3 shows a flowchart of a method according to the invention as per a first example embodiment.

FIG. 4 shows a flowchart of a method as per a second example embodiment.

FIG. 5 shows a graphical illustration of values of the assessment variable obtained when carrying out the method as in FIG. 4.

FIG. 6 shows a flowchart of a method as per a third example embodiment.

### DETAILED DESCRIPTION

FIG. 1 shows a cross-sectional illustration of an object 10 in the form of an industrially produced workpiece. Along its surface 12, the object 10 has a plurality of surface regions 14 to be measured, which differ geometrically from the remaining and preferably substantially planar surface 12 in the shown case. These surface regions 14 are so-called measurement elements, which have predetermined geometric properties and, for example, can be identified and/or selected either by an operator or automatically by a computer device 100, preferably based on a CAD model in each case. From right to left, a bore 14A, a projection 14B and a plateau 14C are shown as corresponding surface regions 14.

Predetermined properties, which should be ascertained by measurement, are specified for each of these surface regions 14. These are so-called test features. By way of example, this can be a diameter or depth in the case of the bore 14A, the height in the case of the projection 14B and a planarity of its surface in the case of the plateau 14C. Such test features can be specified, once again by an operator or automatically by a computer device 100.

In order to ascertain these properties, a measurement sensor 16 is disposed on a coordinate measuring machine 18, only indicated schematically, which, e.g., is embodied in conventional fashion and with three mutually orthogonal machine axes. In the example shown, the measurement sensor 16 is a tactile sensor. However, an optical sensor in the form of a camera, for example, could also be used.

In a manner known per se, this measurement sensor 16 should be positioned by the coordinate measuring machine 18 at at least one specific position and/or with at least one specific orientation per surface region for the purposes of measuring the desired properties of the surface regions 14. By way of example, to capture a bore diameter, it may be necessary to ascertain the coordinates of at least three points on the circumference of the bore, wherein each point corresponds to a specific position to be adopted in this surface region 14.

By way of example, an orientation to be adopted can be specified if the measurement sensor 16 is an optical sensor and the latter should capture images of the surface regions 14, for example. Properties of the aforementioned type can likewise be ascertained from such images in a manner known per se by way of an image evaluation.

Thus, in summary, the measurement sensor 16 must be moved from position to position or from orientation to orientation, which are assigned to the respective surface regions 14, by the coordinate measuring machine 18. These movements represent a non-value-adding time loss within the measurement procedure since no measurement information is obtained in the process. Therefore, it may be desirable to keep this time loss as low as possible, particularly when measuring complex and/or numerous workpieces, or else when measuring with a manufacturing frequency.

Below, only one specific position to be adopted in which the measurement sensor 16 should be arranged (i.e., only a single measurement point) is assumed per surface region 14 in purely example fashion. It is understood that a plurality of such specific positions may also be adopted for each surface region 14.

The single position per surface region 14 discussed below in purely example fashion can be a start or end position, which the measurement sensor 16 has to assume to ascertain at least one predetermined property of a respective surface region 14. In particular, this can be a start position if the surface region 14 should be approached (for example, proceeding from a previously measured surface region 14) and this can be an end position if the surface region 14 should be left (for example, in order to drive to a surface region 14 to be subsequently measured).

It is understood that, on account of the number of surface regions 14, there are a number of options for corresponding measurement sequences or sorts for working through (i.e., for successively measuring) the surface regions 14. In general, there are n! possible measurement sequences or sorts (or (n−1)! if a fixed start point is specified) for n surface regions 14 to be approached. Herein, these can also be referred to as routes.

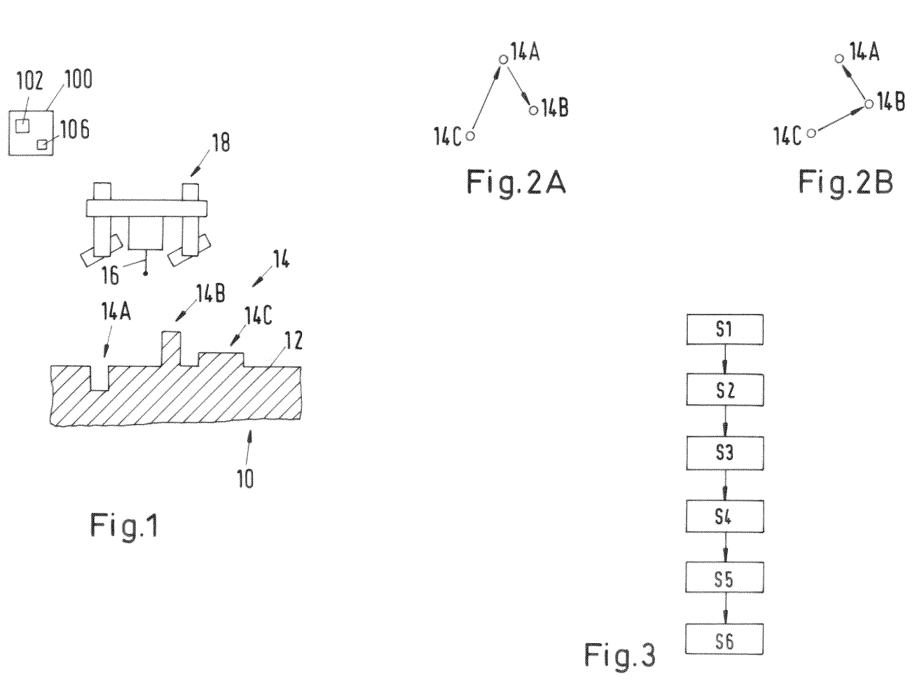

FIGS. 2A-B show two selected routes, wherein the corresponding surface regions 14 of FIG. 1 are referenced by means of the associated geometric features 14A-C and, as explained above, are represented as at least one specific position to be approached in each case. It is possible to identify that the plateau 14C can be chosen as an initial position and that, subsequently, the bore 14A can be measured first, followed by the projection 14B (FIG. 2A). However, proceeding from the plateau 14C, the projection 14B could likewise be measured first and the bore 14A could be measured only subsequently (FIG. 2B). Likewise, the projection 14B or the bore 14A could be selected as the source point instead of the plateau 14C and alternative routes can be determined proceeding therefrom.

On account of properties of the coordinate measuring machine 18, of the measurement sensor 16 and/or of the object 10, there may also be a difference whether for example the bore 14A is approached from the plateau 14C or, conversely, the plateau 14C is approached from the bore 14A, for example for collision avoidance or on account of the scope of movement of the machine axes.

Consequently, a multiplicity of possible measurement sequences (or sorts or routes) are therefore available for selection, which are each accompanied by associated movement profiles of the measurement sensor 16 so as to be able to move the latter from measurement element to measurement element (or from surface region 14 to surface region 14).

Known TSP algorithms, as can be executed by a computer device 100, which is schematically illustrated in FIG. 1 and which comprises at least one microprocessor 102, can be used to ascertain which of the measurement sequences available for selection is optimal in view of an assessment variable relevant from the point of view of the user.

To this end, the computer device 100 may comprise a storage device 16, in which the surface regions 14 to be measured and properties to be determined to this end are stored. By way of example, this can be set by user inputs and/or automatically by suitable algorithms, which evaluate a CAD model of the object.

The optimal measurement sequence can be selected by the computer device 100, either automatically or in response to a corresponding user input, and can be used to control the coordinate measuring machine 18 so that the latter implements the measurement sequence. For the sake of completeness, it is mentioned that the computer device 100 could be a conventional PC. However, it could likewise be a control device of the coordinate measuring machine 18 or a server (e.g., a cloud server).

According to rules defined therein, the TSP algorithms successively change the measurement sequence (i.e., work through a plurality of varying measurement sequences and ascertain the value of the assessment variable for a respective measurement sequence).

In the presently shown case, the assessment variable is the overall measurement time duration required, which is decisively determined by the necessary movements between the individual surface regions 14. Consequently, the measurement time duration can also be considered to be only this movement duration for moving the measurement sensor 16 between the individual surface regions 14, or else the distance or the extent of the machine axis movements required to this end.

As will still be explained below, the respectively ascertained assessment variables can be evaluated to the effect of which measurement sequence renders a (local or absolute) optimum of the assessment variable and, in the shown examples, a (local or absolute) minimum of the assessment variable reachable.

According to the invention, two algorithms are used in the examples discussed below. Here, this is preferably a TSP algorithm in each case. Various options of how these algorithms can be combined and/or can interact with one another in order to ascertain an optimal measurement sequence (i.e., a measurement sequence with an optimal value of the assessment variable and, in particular, with a minimum value of the assessment variable) are highlighted below.

FIG. 3 shows a flowchart for a method according to the invention according to a first example embodiment. Here, two TSP algorithms are carried out in succession, in particular in such a way that the execution thereof does not overlap in time or that the second TSP algorithm builds on results of the first TSP algorithm.

The surface regions 14 to be measured are obtained in a step S1, preferably together with properties to be ascertained to this end, e.g., from an operator or from the manual or automatic evaluation of a CAD model of the object 10.

Thereupon, at least one position and/or orientation is ascertained for each surface region 14 in a step S2, which position and/or orientation must be adopted by the measurement sensor 16 in order to ascertain the desired properties of the surface regions 14. Such ascertainments are known and are also used in currently available solutions. To this end, (expected) coordinates of the object 10 and, in particular, of its surface regions 14 can be ascertained in the working space of the coordinate measuring machine 18 based on computer simulation, for example, and the positions to be approached and/or the orientation to be set by the coordinate measuring machine 18, in each case of the measurement sensor 16, can thereupon be ascertained.

It is also known that the movements explained based on FIGS. 2A-B and, in particular, individual machine axis movements of the coordinate measuring machine 18 for moving the measurement sensor between the different surface regions 14 are also ascertainable, for example by means of conventional NC algorithms. In particular, required movement distances and/or movement time durations can also be ascertained on the basis thereof.

However, the algorithms presented herein are primarily directed to finding a measurement sequence in which these movements of the measurement sensor 16 or of the coordinate measuring machine 18, which were preferably ascertained differently or by means of other algorithms, have desired properties and, in particular, are executed particularly quickly. This is because sorting or stringing together the surface regions 14 according to a measurement sequence decisively determines the type and the extent of the required movements, which then, in turn, can be quantified accurately by means of other algorithms (but optionally also by means of the TSP algorithms themselves). However, the TSP algorithms are in any case configured to ascertain values of the assessment variable, wherein, however, it is also possible to resort to information ascertained by other algorithms.

A first (TSP) algorithm is carried out in a step S3, the algorithm defining a measurement sequence and changing the latter multiple times based on the information ascertained in step S2, the measurement sequence specifying the order in which the surface regions 14 should be measured. Here, the first algorithm ascertains an assessment variable for each measurement sequence, the assessment variable being the measurement time duration required in the present example.

To this end, the algorithm can calculate and, in particular, simulate the required machine movements or machine axis movements, for example, once again by means of known algorithms as specified above, in order to be able to work through a currently considered measurement sequence. The time duration of the required machine axis movements can be measured by means of the simulation. Alternatively, this time duration can be calculated, for example with knowledge of a drive power and the extent or the traversed distance of the machine axis movements

The assessment variables ascertained overall are considered in a step S4 and an optimal one thereof is selected. In the shown example, this is the smallest assessment variable, i.e., the shortest measurement time duration required. Then, the associated measurement sequence is selected in a step S5 and chosen as start sequence or initial route or else as source variable for a second (TSP) algorithm.

Proceeding from this initial route and according to rules set by the algorithm, the latter starts in step S6 to successively change this initial measurement sequence in such a way that further improvements of the assessment variable set in with a certain probability. By way of example, this is relevant if, although the first algorithm has already found a local optimum of the assessment variable, it has not found an absolute optimum because the first algorithm, under certain circumstances, cannot independently escape from a local optimum (i.e., it cannot leave the latter again by accepting a temporary deterioration as this is incompatible with the rules for changing the measurement sequence stored in the algorithm).

It is also possible that, although the first algorithm has found an optimum of the assessment variable from its point of view, the actual absolute optimum has not yet been reached since this needs further changes, possibly even only small further changes, in the measurement sequence. Expressed differently, change increments or change extents of the first algorithm may be comparatively coarse or not have a sufficiently fine resolution, and so the latter may jump over an actual optimum of the assessment variable.

Therefore, proceeding from the initial route already assessed as particularly suitable, the second algorithm can undertake further changes in the measurement sequence in step S6 and thus increase the probability of finding the actual absolute optimum.

Here, different types of algorithms and, in particular, algorithms with different properties are combined with one another in the shown example. The first algorithm is a nearest neighbor algorithm and the second algorithm comprises a meta-heuristic, as already discussed in each case in the general part of the description above.

Phrased in general, the first algorithm is distinguished by a comparatively higher computational speed since it reaches what it considers to be an optimum of the assessment variable more quickly. By contrast, the first algorithm may not escape from a local optimum (in particular a local minimum) under certain circumstances and/or may not identify whether the obtained optimum is a local or an absolute optimum. By contrast, due to the meta-heuristic, the second algorithm, which is comparatively slower, is defined in such a way that it can escape from local optimums and, in particular, from a local minimum and consequently has increased chances of still reaching an absolute optimum after reaching the local optimum.

Thus, the possibility of finding the absolute optimum comparatively quickly arises due to the combination of different algorithms provided in the example embodiment of FIG. 3. By way of example, the first algorithm could directly ascertain the absolute optimum, which could then be confirmed by the second algorithm, or the first algorithm could ascertain a local optimum located in the vicinity of this absolute optimum such that the second algorithm only still needs a few changes in order to arrive at the actual absolute optimum. This can be faster, particularly in comparison with a case where the second algorithm initially proceeds from any route or initial route and consequently, under certain circumstances, requires many changes and a long calculation time to reach the absolute optimum. The first algorithm could also carry out a specified maximum number of iterations or measurement sequence variations and output to the second algorithm the previously best intermediate result as initial measurement sequence when this number has been reached.

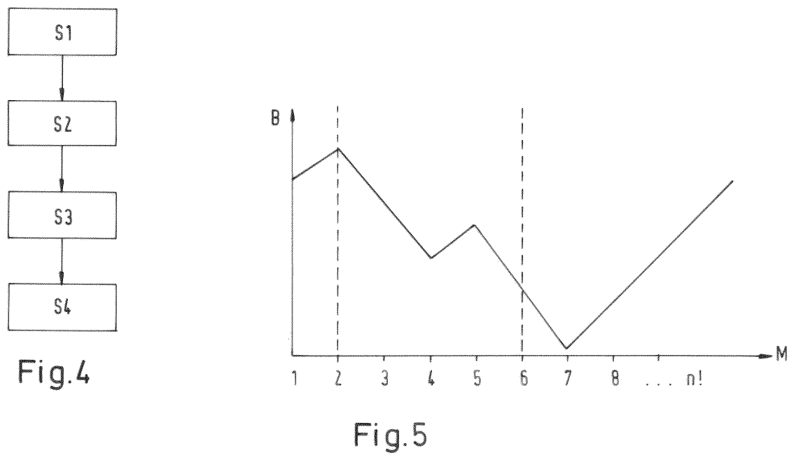

Below, a method according to a further example embodiment is explained based on FIGS. 4 and 5. In this case, two (TSP) algorithms are carried out with time overlap and are preferably also started simultaneously. Here, the algorithms are similar but could, in principle, also be different. In any case, the algorithms proceed from different initial routes (i.e., from different initial measurement sequences). Proceeding from their initial route, they then carry out changes in the measurement sequence according to the rules stored in the algorithm in order to minimize the assessment variable (once again, the required measurement time duration in the shown example).

The two algorithms are selected in a step S1. Preferably, these are algorithms with meta-heuristics and/or, in general, algorithms configured to escape from local optimums (i.e., with a high probability of still being able to find a further optimum after an at least local optimum has already been found) in both cases.

An initial measurement sequence is obtained or determined in a step S2, the initial measurement sequence, however, being changed, e.g., by means of a random variable for each of the algorithms such that these proceed from a different (changed) initial measurement sequence. Expressed differently, the algorithms receive initial measurement sequences that each have random or deterministic noise, and so the initial measurement sequences of the algorithms differ from one another.

A procedure can be referred to as deterministic if it contains no random values or is not based thereon. By way of example, at least two surface regions within a measurement sequence can be interchanged as per a defined prescription provided that possible conditions, such as the dependencies explained below, remain satisfied in the process.

To this end, a sequence can be calculated, for example based on an overall number of surface regions, according to which sequence the surface regions should be strung together as an initial measurement sequence. More precisely, the surface regions can be indexed and this can be followed by reindexing based on the overall number of surface regions and/or a fixed number of maximum variations of the measurement sequence, according to which the initial measurement sequence is set.

Thus, the surface region with the (previous) index 0 can be chosen, e.g., for the first surface region of the reindexed measurement sequence. The surface region with the (previous) index corresponding to half the total number of considered surface regions can be chosen as a second surface region. Then, similar rules can be created for the further ordering of the surface regions, preferably in such a way that no surface region is present twice in the reindexed measurement sequence. However, each algorithm should proceed with at least a slight deviation such that initial routes with different noise are obtained.

In step S3, the algorithms start, in conventional fashion, to change their respective initial measurement sequences successively according to the rules stored in the algorithm and to determine a value of the assessment variable (measurement time duration) for each changed measurement sequence.

This is further elucidated in FIG. 5, in which a value of the assessment variable obtained for each measurement sequence is plotted over the population of total possible measurement sequences (as shown above, n! possible measurement sequences in the case of n surface regions 14). In this representation, the measurement sequences are preferably plotted along the horizontal axis in such a way that these only have one permutation with respect to each adjacently plotted measurement sequence (i.e., with respect to both a preceding and a subsequent measurement sequence). Expressed differently, only one pair of the surface regions 14 can be contained in interchanged sequence in relation to the respectively adjacent measurement sequences. For an example group of surface regions A, B, C, the following succession of sequences could be plotted along the horizontal axis in accordance with this prescription: ABC; ACB; BAC; BCA; CAB; CBA.

However, on account of the different initial measurement sequences, the algorithms proceed from different start points within the population of measurement sequences, as indicated by the dashed vertical lines.

In more detail, a first algorithm proceeds from the measurement sequence denoted by 2 and the second algorithm proceeds from the measurement sequence denoted by 6. It is understood that even further algorithms could be started, preferably simultaneously, and these would then proceed from further measurement sequences.

From the profile of the values of the assessment variable, it is possible to identify that the latter has an absolute maximum (in the mapped section) at the measurement sequence 2, a local minimum at the measurement sequence 4, a local maximum at the measurement sequence 5 and an absolute minimum at the measurement sequence 7.

This also visualizes the aforementioned problem, according to which some algorithms can no longer escape from a local optimum or are not able to find a further local optimum, or possibly even an absolute optimum, proceeding therefrom: If a local minimum were to be ascertained at the measurement sequence 4, an insufficiently large change in the measurement sequence would lead to the assessment variable increasing again. This may be incompatible with the rules of the algorithm and/or represent a termination criterion, and so this algorithm would ascertain the measurement sequence 4 as best measurement sequence from its point of view and would no longer find the absolute minimum at the measurement sequence 7.

Returning to the example embodiment, it is possible to identify that the algorithm proceeding from measurement sequence 6 is already located in the vicinity of the optimal measurement sequence 7. Therefore, it is likely that only a few changes are required until this algorithm has in fact ascertained this measurement sequence 7 as an absolute optimum. This applies, in particular, in comparison with the algorithm which proceeds from measurement sequence 2 and which would require comprehensive changes in order to arrive at the measurement sequence 7. In particular, the local minimum at measurement sequence 4 would have to be overcome to this end.

One of the algorithms finding an optimum and satisfying a predetermined termination criterion, a suitable example of which was explained in the general part of the description, may immediately lead in step S4 to the end of the method and to the selection of the measurement sequence with the previously best assessment variable (e.g., the minimum assessment variable).

All example embodiments are also usable in variants in which an object 10 is measured with a plurality of coordinate measuring machines 18 and measurement sensors 16. By way of example, two coordinate measuring machines 18 could be disposed either side of an object 10 and measure the latter simultaneously with respectively one measurement sensor 16. Dividing measurement elements or surface regions 14 between the coordinate measuring machines 18 such that each coordinate measuring machine 18 measures a certain group of measurement elements of the object 10 in respect of relevant test features is known in this context. However, this division was previously implemented by hand and required experience.

Accordingly, according to a further embodiment, at least one TSP algorithm, preferably at least two TSP algorithms, which are combined according to one of the variants explained herein, for example, can be provided to select and set an optimal measurement sequence also in view of the surface regions 14 being measured by different coordinate measuring machines 18 and/or measurement sensors 16, i.e., in view of the surface regions being optimally split between the coordinate measuring machines 18. In this case, too, it may be once again preferred for movements between the surface regions 14 to be measured to be as small as possible. According to the invention, such a division can be successful using algorithms for solving the so-called “multiple traveling salesman problem” or a “vehicle routing problem”, which are both derivatives of the traveling salesman problem.

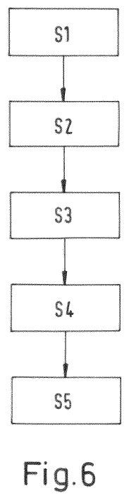

FIG. 6 shows a flowchart for a method according to a further example embodiment. The use of at least two algorithms is not mandatory in this method; however, it may likewise be provided. If use is made of at least two algorithms, this can be implemented according to any of the variants and embodiments explained herein. Secondly, at least one condition that has to be observed by the measurement sequence so that this can ultimately be selected as the measurement sequence to be carried out by the coordinate measuring machine is taken into account in the embodiment of FIG. 6.

In a manner analogous to the preceding example embodiment, the surface regions 14 of an object 10 to be measured are obtained in step S1. Then, in a step S2, a measurement sequence is determined by the at least one algorithm and the former is changed multiple times, with a changed measurement sequence and associated assessment variable being ascertained for each change. This is once again implemented in analogous fashion to the preceding example embodiments.

Then, only the measurement sequences that satisfy a predetermined condition are selected in a step S3 from all the ascertained and assessed measurement sequences. The final selection of the measurement sequence that was ascertained as valid (i.e., satisfying the condition) in the preceding step S3 and that has the, e.g., minimum or maximum assessment variable is then implemented in step S4. This can then be implemented by the coordinate measuring machine 18 for measuring the object 10 in the optional step S5.

However, the condition can also be taken into account directly when changing the measurement sequence. By way of example, only the measurement sequences that satisfy the condition can be in fact assessed or otherwise pursued by the algorithm. In particular, whether an intended change leads to a measurement sequence that satisfies the condition can be checked directly when changing the measurement sequence. Should this not be the case, this measurement sequence may not be generated, stored, assessed, or further processed differently.

Examples of appropriate conditions are specified in the general part of the description. By way of example, this can be the observance of a freedom from collisions. In particular, this may however relate to the observance of a predetermined relative relationship between surface regions. This relative relationship can be generally temporal (i.e., two surface regions may only be measured within a predetermined maximum time interval, i.e., must not be measured outside of this predetermined time interval). In addition or as an alternative thereto, the relative relationship can define a (measurement) succession of the surface regions to be observed, for example if one of the surface regions has to be measured before the other since a property of the other surface region to be determined depends on a property of the first surface region to be determined.

The phrase at least one of A, B, and C should be construed to mean a logical (A OR B OR C), using a non-exclusive logical OR, and should not be construed to mean “at least one of A, at least one of B, and at least one of C.”

1. A method for setting a measurement sequence for a coordinate measuring machine, the method comprising:
obtaining a plurality of surface regions of an object to be measured by a measurement sensor in respect of at least one predetermined property, wherein, to measure a respective surface region, the measurement sensor is arranged by the coordinate measuring machine according to at least one of a specific position and a specific alignment;
changing a measurement sequence, in which to measure the surface regions, multiple times using a first algorithm and using a second algorithm, wherein, with each change of the measurement sequence, the first and second algorithms each ascertain a changed measurement sequence and an assessment variable; and
selecting one of the measurement sequences based on the ascertained assessment variables, wherein at least one of:
the first algorithm ascertains an initial measurement sequence as a start sequence for the second algorithm and has a higher computational speed than the second algorithm, and
the first and the second algorithm are carried out at least partially in parallel.
